(19) United States
(12) Patent Application Publication
(10) Pub. No.: US 2025/0118564 A1
(43) Pub. Date: Apr. 10, 2025

(54) Method for Thinning a Semiconductor Substrate

(71) Applicant: IMEC VZW, Leuven (BE)

(72) Inventors: Eric Beyne, Heverlee (BE); Liesbeth Witters, Lubbeek (BE)

(21) Appl. No.: 18/906,945

(22) Filed: Oct. 4, 2024

(30) Foreign Application Priority Data
Oct. 6, 2023 (EP) 23202138.6

(51) Int. Cl. H01L 21/306; H01L 21/02; H01L 21/20; H01L 21/762; H01L 21/768

(52) U.S. Cl. CPC H01L 21/30608; H01L 21/02164; H01L 21/2007; H01L 21/76229; H01L 21/76807

(57) ABSTRACT

A layer of semiconductor devices is produced on the frontside of a crystalline semiconductor substrate, in regions separated by dielectric-filled cavities formed previously. Additional layers are then formed on the device layer. The substrate is then flipped and bonded face down to a second substrate, following by the thinning of the crystalline first substrate from the backside. The thinning proceeds as far as possible without removing the full thickness of the first substrate anywhere across its surface. After this, an anisotropic etch is performed to remove additional material of the first substrate. The in-plane dimensions of the device regions separated by the dielectric-filled cavities are specified so that the anisotropic etch is stopped by a crystallographic plane of the substrate material or by the dielectric material in the cavities, before it can reach the devices on the frontside.

### CROSS-REFERENCE TO RELATED APPLICATIONS

The present application is a non-provisional patent application claiming priority to European Patent Application No. EP 23202138.6, filed on Oct. 6, 2023, the contents of which are hereby incorporated by reference.

### FIELD OF THE DISCLOSURE

The present disclosure is related to semiconductor processing, in particular to the extreme thinning of a substrate from the backside.

### BACKGROUND

In semiconductor processing, active devices such as transistors and diodes are fabricated on the frontside of a semiconductor substrate, such as a Si process wafer of 300 millimeters in diameter. On top of the devices, a multilayer interconnect structure is built, for routing signals to and from the devices. Traditionally, the delivery of power to the devices was also routed through this frontside interconnect structure. However, recent development has led to the integration of a backside power delivery network, built on the backside of the substrate. Extreme thinning of the substrate from the backside can be utilized to bring the substrate portion to a thickness of less than 500 nanometers. In some embodiments, thinning completely removes the Si substrate, leaving only the active Si devices. Also, in stacked IC configurations, the substrate portion of IC chips may be thinned to similar extremely low thickness values.

Traditionally, thinning takes place by bonding the wafer face down to another process wafer or to a temporary carrier substrate, and removing the bulk of the wafer from the backside thereof, by applying grinding and polishing techniques.

However, no process wafer is perfectly flat. Standard 300 millimeters diameter process wafers have a typical thickness of 775 micrometers with a total thickness variation (“TTV”) of only 1 or a few micrometers. At full thickness this is a relative precision better than 0.2%. After wafer-to-wafer bonding, both the wafer that is to be thinned and the receiving (e.g., carrier or supporting) wafer are subject to such a thickness variation. Therefore, thinning a wafer from the backside to extremely low thickness values by grinding and polishing techniques alone may negatively affect the active devices in one or more areas of the wafer.

An example alternative is the production of ICs on a so-called silicon-on-insulator (“SOI”) wafer, which comprises a thin oxide layer on the bulk silicon, and a thin epitaxially grown Si layer on top of the oxide. The devices and the multilayer interconnect structure are fabricated on this epitaxial Si layer, after which the wafer is bonded face down to another wafer or a carrier. Thinning from the backside by grinding and polishing is then stopped prior to reaching the oxide layer and the remaining bulk silicon is removed by wet etching, wherein the oxide layer acts as an etch stop layer. Thereafter, the oxide itself is removed by etching selectively with respect to the epitaxially grown Si. Instead of an oxide layer, an epitaxially grown SiGe layer can be used as an etch stop layer.

These examples are, however, technically complex and thereby increase the cost of the semiconductor fabrication process.

### SUMMARY

The present disclosure is related to a method in accordance with the claims.

According to the method, a first crystalline semiconductor substrate or other variety of first substrate is provided and a layer of semiconductor devices is produced on the frontside thereof, in regions separated by dielectric-filled cavities, which may include shallow trench isolation regions, formed prior to the device processing. Additional layers such as the layers of a multilayer interconnect structure are formed on the device layer. The substrate is then flipped and bonded face down to a second substrate, followed by the thinning of the first substrate from the backside. The thinning proceeds as far as possible without removing the full thickness of the first substrate anywhere across its surface, e.g., taking into account any intrinsic thickness variation of the first substrate and second substrate.

After this, an anisotropic etch is performed for removing additional material of the first crystalline semiconductor substrate. In accordance with the present disclosure, the in-plane dimensions of the device regions separated by the dielectric-filled cavities are configured so that the anisotropic etch is stopped by a crystallographic plane of the substrate material or by the dielectric material in the cavities, before it can reach the devices on the frontside. Depending on the exact dimensions of the device regions and on possible depth differences between adjacent dielectric-filled cavities, the anisotropic etch may stop when a V-shaped groove is formed in the substrate material. After the anisotropic etch, a further dielectric material is deposited and planarized, along with remaining material of the first substrate.

The method thereby enables thinning the first substrate to a level that may be extremely close to the device layer, within a few tens of nanometers for example, without running the risk of inadvertently removing or damaging devices in the device layer. An etch stop layer is shown in some embodiments and the method is applicable to a substrate that is integrally formed of the same material. Such a method can exhibit reduces process complexity and number of steps, thereby improving yield and reducing costs and fabrication time.

The present disclosure includes a method for producing a thinned semiconductor substrate, comprising: providing a first substrate having a planar frontside and a planar backside, the first substrate comprising a crystalline semiconductor material on the planar frontside; producing a device layer on the planar frontside of the first substrate, the device layer comprising, in a first area, a plurality of semiconductor devices; producing, in the first area, before producing the device layer, a plurality of cavities from the planar frontside of the first substrate and into the crystalline semiconductor material of the first substrate; at least partially filling the plurality of cavities with a dielectric material; forming an additional dielectric layer over the plurality of semiconductor devices located in the first area; producing an additional layer on top of the device layer, ending with a planar top surface; bonding the first substrate to a second substrate by bonding the planar top surface to a bonding surface of the second substrate; and subsequent to bonding the first substrate to the second substrate, thinning the first substrate from the planar backside such that a uniform layer of the crystalline semiconductor material remains above the plurality of cavities; and subjecting the crystalline semiconductor material to an anisotropic etch process that stops at (i) a specified crystallographic plane of the crystalline semiconductor material, (ii) the dielectric material in at least one of the plurality of cavities, and (iii) the additional dielectric layer, wherein in-plane dimensions of a plurality of regions located between the plurality of cavities and depths of the plurality of cavities are configured such that the anisotropic etch process does not reach any of the plurality of semiconductor devices.

According to an embodiment, after the anisotropic etch process, the method further comprises: depositing a further dielectric material on a thinned backside of the first substrate; and planarizing the further dielectric material and remaining portions of the crystalline semiconductor material to a common planarized surface.

According to an embodiment, producing a second plurality of cavities in a second area of the first substrate wherein producing the device layer does not include producing any semiconductor devices in the second area.

According to an embodiment, a spacing between two adjacent cavities of the second plurality of cavities is configured so that the anisotropic etch process does not reach the planar frontside of the first substrate between the two adjacent cavities of the second plurality of cavities.

According to an embodiment, the plurality of cavities in the first area define shallow trench isolation (STI) regions.

According to an embodiment, the crystalline semiconductor material is crystalline silicon.

According to an embodiment, the first substrate is a silicon process wafer having the planar frontside and the planar backside oriented along the (100) crystallographic plane of crystalline silicon.

According to an embodiment, a plurality of scribe lines divides a plurality of die areas of the silicon process wafer.

According to an embodiment, at least one cavity of the plurality of cavities is formed in one of the plurality of scribe lines between an adjacent pair of the plurality of die areas.

According to an embodiment, a plurality of scribe lines divides a plurality of die areas of the first substrate, and at least one cavity of the plurality of cavities is formed in one of the plurality of scribe lines between an adjacent pair of the plurality of die areas.

According to an embodiment, the in-plane dimensions of the plurality of regions located between the plurality of cavities and the depths of the plurality of cavities are configured such that the anisotropic etch process stops when a V-shaped groove is formed in the crystalline semiconductor material of the first substrate.

According to an embodiment, the in-plane dimensions of the plurality of regions located between the plurality of cavities and the depths of the plurality of cavities are configured such that the anisotropic etch process stops on crystallographic planes of the crystalline semiconductor material.

According to an embodiment, the in-plane dimensions of the plurality of regions located between the plurality of cavities and the depths of the plurality of cavities are configured such that the anisotropic etch process stops on the dielectric material in at least one of the plurality of cavities.

According to an embodiment, the in-plane dimensions of the plurality of regions located between the plurality of cavities and the depths of the plurality of cavities are configured such that the anisotropic etch process stops on the additional dielectric layer.

According to an embodiment, the further dielectric material is deposited after the plurality of cavities are filled at least partially with the dielectric material, to form a second layer of dielectric material.

According to an embodiment, the further dielectric material is a pre-metal dielectric (PMD).

According to an embodiment, the further dielectric material is at least one of SiO₂ or a low-K material.

According to an embodiment, an interconnect via and a conductor are produced in the second layer of dielectric material.

According to an embodiment, the interconnect via and the conductor are produced in the second layer of dielectric material by a technique comprising at least one of a single or double damascene processes.

According to an embodiment, the first substrate is bonded to the second substrate at a bonding layer comprising at least one of SiO₂, SiCN, or a hybrid bonding layer comprising the dielectric material and metal contact pads coplanar therewith.

The terms “frontside” and “backside” of a substrate refer respectively to the two mutually opposite (main) sides of the substrate.

### BRIEF DESCRIPTION OF THE FIGURES

The above, as well as additional objects, features, and benefits, may be understood through the following illustrative and non-limiting detailed description, with reference to the appended drawings. In the drawings, like reference numerals will be used for like elements unless stated otherwise.

FIG. 1A, FIG. 1B, and FIG. 1C illustrate a process wafer and a layout of multiple dies on the wafer, according to an example embodiment.

FIG. 2 illustrates a section view of the smaller region of the process wafer as shown in FIG. 1C, according to an example embodiment.

FIG. 3 illustrates a section view of the smaller region of the process wafer with a number of trenches, according to an example embodiment.

FIG. 4 and FIG. 5 illustrate a section view of the smaller region of the process wafer with a dielectric material within the trenches, according to an example embodiment.

FIG. 6, FIG. 7, and FIG. 8 illustrate a section view of the smaller region of the process wafer with a dielectric material deposited in the trenches, according to an example embodiment.

FIG. 9 illustrates a section view of the smaller region of the process wafer thinned from the backside, according to an example embodiment.

FIG. 10 and FIG. 11 illustrate a section view of the smaller region of the remaining process wafer as shown in FIG. 9, further thinned, according to an example embodiment.

FIG. 12 and FIG. 13 illustrate a section view of the smaller region of the process wafer with a layer of dielectric material that forms a uniform layer, according to an example embodiment.

FIG. 14, FIG. 15, and FIG. 16 illustrate a thinning method, according to an example embodiment.

FIG. 17, FIG. 18, and FIG. 19 illustrate a section view of the smaller region of the process wafer with additional dielectric-filled cavities, according to an example embodiment.

All the figures are schematic, not necessarily to scale, and generally only show parts to elucidate example embodiments, wherein other parts may be omitted or merely suggested.

### DETAILED DESCRIPTION

In the following detailed description, all references to specific materials and dimensions are included by way of example only, and none of these citations are to be construed as limitations of the protection scope.

The embodiments of the present disclosure will now be described more fully with reference to the accompanying drawings, in which various example embodiments are shown. The concepts of the present disclosure may, however, be embodied in many different forms and should not be construed as limited to the specific embodiments set forth herein; rather, these embodiments are provided for thoroughness and completeness, and to fully convey the scope of the present disclosure to the skilled person.

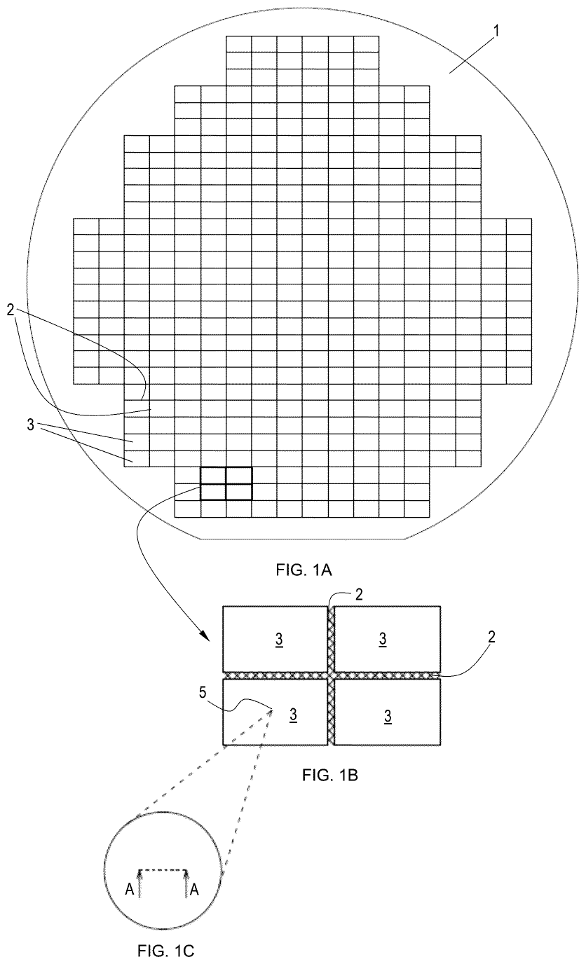

FIG. 1A illustrates a process wafer 1, which may be a crystalline silicon wafer, or a standard process wafer of 300 millimeters in diameter and having a thickness of a 775 micrometers. Scribe lines 2 divide the wafer surface into a plurality of die areas 3. Four adjacent die areas 3 are represented in an enlarged image in FIG. 1B. In these die areas 3, a given layout of active devices such as transistors and diodes are produced by a sequence of process steps. Each die area 3 may a few tens of square millimeters and packed with nanometer-sized devices in the finished die. The scribe lines 2 are wide enough to enable singulating the finished dies 3, and may serve also as areas for printing auxiliary features such as metrology marks.

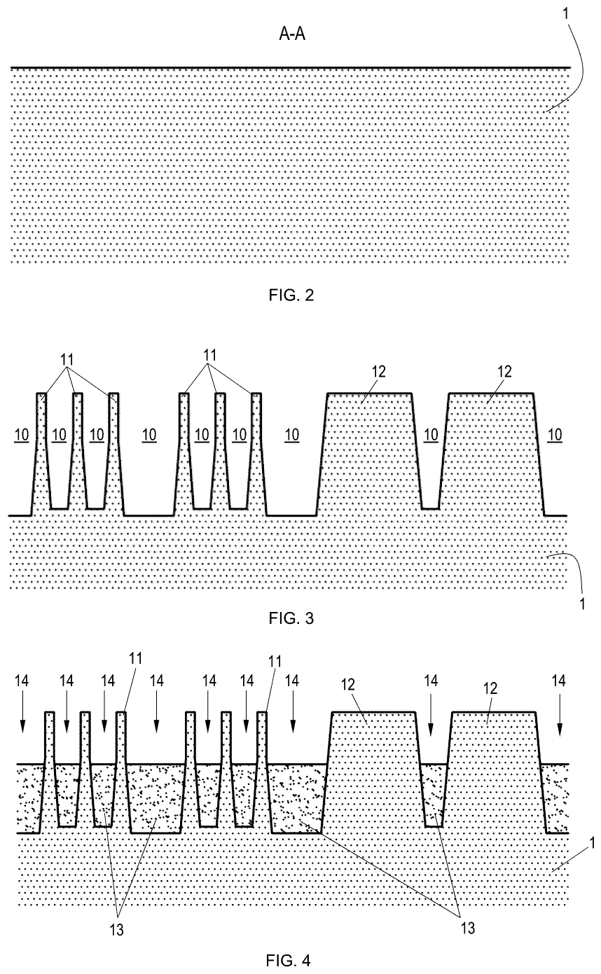

The method of the present disclosure is explained on the basis of a nanometer-sized section along line A-A in one die area 3, as indicated in FIG. 1C, which shows an enlargement of a spot 5 in the die 3 area. The section view of this small region is represented in a further enlarged view in FIG. 2. Only a thin upper portion of the wafer 1 is shown, the portion having a thickness of a few hundred nanometers. In an example embodiment, the wafer is integrally formed of a crystalline semiconductor material, although a composite wafer having a top layer of crystalline semiconductor material can also be applied in the method of the present disclosure.

By lithography and etching, and as illustrated in FIG. 3, a number of trenches 10 are formed through the front surface of the wafer 1, thereby defining semiconductor structures as fins 11 and larger structures 12 separated by the trenches 10. In the embodiment illustrated in FIG. 3, two groups of fins 11 are created and two larger structures 12. The fins 11 may have a width at their top of a few nanometers or a few tens of nanometers, for example, and are typically formed with the purpose of processing finFET transistors. The larger structures 12 may be dummy areas or the larger structures 12 may be intended for processing other types of devices thereon such as planar transistors or diodes. Lithography and etch steps for producing patterns of this type are well known in the art and details thereof are therefore not in some embodiments for explaining the present disclosure.

With reference to FIG. 4, a dielectric material 13 is deposited and etched back selectively with respect to the fins 11 and the larger structures 12 to a level between the base and the top of the fins 11 and larger structures 12. This is the creation of shallow trench isolation (“STI”) regions 14, applied for electrically isolating adjacent devices. The dielectric material 13 may be silicon oxide or any suitable material known for this purpose.

The STI regions 14 may also be known as dielectric-filled trenches and are embodiments of the broader term “dielectric-filled cavities” used in claim 1. A trench is an elongate cavity, whose length is considerably longer than its width. STI regions 14 for isolating devices are commonly produced in the form of such elongate cavities, e.g., trenches. However, other areas on a chip may include dielectric-filled cavities of other shapes, in particular square or rectangular with a smaller difference between the length and the width of the rectangle. The presence of dielectric-filled cavities plays a major role in the present disclosure, as will be explained later in this description.

According to embodiments of the present disclosure, dielectric-filled trenches or other cavities may be formed in areas where such trenches or cavities are not found in other designs, for example in the scribe lines 2 between adjacent die areas 3.

Following the creation of the STI regions 14 or dielectric-filled trenches, processing of the actual semiconductor devices is performed. This involves many process steps that are not described here in detail but which may be adapted to the fabrication of desired semiconductor structures, devices, or other elements of a desired device or system.

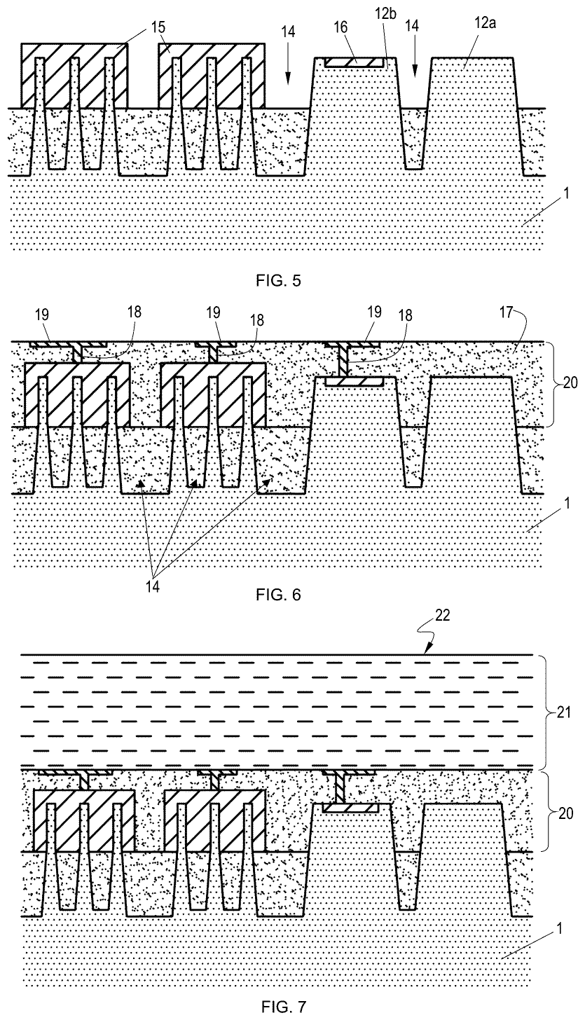

The result is represented in a simplified form in FIG. 5. Device regions 15 are formed on the two groups of fins. These may be gate areas of finFETs, for example. One of the larger areas 12a can be a dummy area while the other 12b has received a planar device 16 on its upper surface.

Further known steps are illustrated in FIG. 6 and FIG. 7. A further dielectric material 17 is deposited and planarized. This is a material suitable to serve as a pre-metal dielectric (“PMD”), for example SiO₂ or a low-K material. Interconnect vias 18 and conductors 19 are produced in the PMD layer 17 by techniques such as single or double damascene processes. The planarized PMD layer 17, with devices embedded therein, is referred to as a ‘device layer’ 20 in the present context. This device layer may correspond to the front end of line portion of a chip, including also a first metallization level sometimes referred as the MO level or the middle end of line.

On the device layer 20, as shown in FIG. 7, further layers of interconnect vias and conductors are processed, which may correspond to the back of end line (“BEOL”) portion of an integrated circuit. In the embodiment shown, the BEOL portion is schematically represented as a layer 21 having a planar top surface 22.

The wafer is then flipped and attached face down to another substrate. For this purpose, the planar top surface 22 of the BEOL portion 21 may be the surface of a dielectric bonding layer formed, for example, of SiO₂ or SiCN, or a hybrid bonding layer comprising dielectric material and metal contact pads coplanar therewith. Such bonding layers are suitable for use in a wafer to wafer direct bonding process which may involve a heating step for forming a strong bond.

Alternatively, the planar top surface 22 of the BEOL portion 21 may be suitable for temporarily bonding the wafer face down to a temporary carrier wafer. This latter case is illustrated in FIG. 8. The temporary carrier 23 and a removable adhesive layer 24 are indicated, with the BEOL portion 21 attached so that the bulk of the process wafer 1 is facing upwards. Suitable types of carrier wafers and adhesives for this purpose are equally well-known to persons skilled in the art.

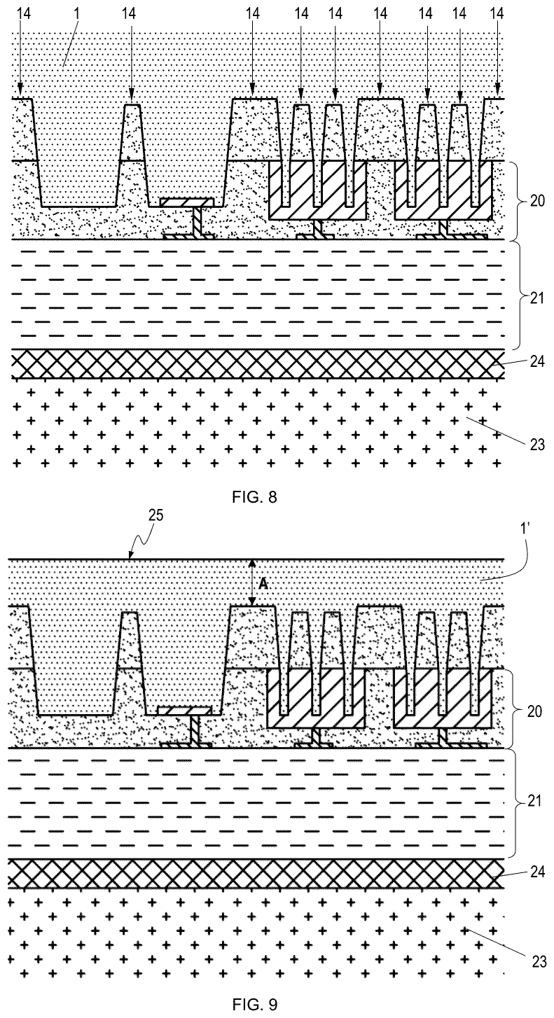

With reference to FIG. 9, the wafer 1 is then thinned from the backside. This may be done by any thinning method known in the art, for example by first using a grinding technique in order to remove a large portion of the wafer's bulk material in a short time span. An etch process can be used instead of a grinding technique. In an example embodiment, the grinding or etching process is followed by polishing, applying a form of chemical mechanical polishing (CMP) to further reduce the thickness at a slower rate, ending up with a smooth back surface 25 of the thinned wafer 1. Alternatively, a further etch process may be applied to arrive at the back surface 25.

At this point, the remaining silicon substrate bulk thickness A, indicated in FIG. 9, is not constant across the surface of the wafer 1, with variations in the micrometer range, due to the intrinsic thickness variation of both the wafer 1 and the carrier 23 and possibly due to a degree of non-uniformity of the applied thinning techniques. The initial thinning to arrive at the situation shown in FIG. 9 is configured so that the wafer 1 is reduced to a uniform layer 1′ of wafer material remaining above the dielectric-filled trenches 14, e.g., such that none of the dielectric-filled trenches 14 is exposed by the thinning process. Taking into account common values of thickness variations on a process wafer, an average thickness A of for example 500 nanometers to 1 μm can, in some examples, satisfy this condition. The actual average of the thickness A may be lower if the thickness variation of the applied substrates is lower than the commonly encountered values.

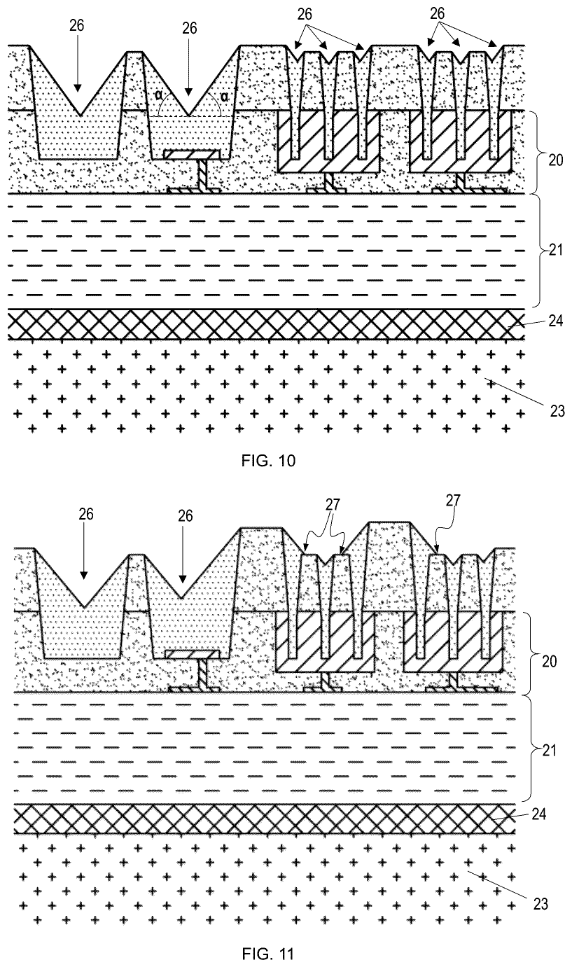

In accordance with the present disclosure, the remaining wafer material is further thinned by an anisotropic etch process, as illustrated in FIG. 10, that removes the wafer material selectively with respect to the dielectric-filled trenches 14. The process is anisotropic. It removes the bulk semiconductor material of the wafer 1 along specific crystallographic planes of the wafer material. This type of process is known as such and used for example for making pyramid-shaped indentations in the surface of a semiconductor wafer. For example, when the wafer 1 is a Si wafer with its flat surfaces oriented along the (100) crystallographic plane, a KOH or TMAH etch process will remove the Si along the (111) planes which are oriented at about 540 with respect to the (100) plane.

Due to the anisotropic nature of the etch process and due to the selectivity of the etch process relative to the dielectric material in the trenches 14, the etch process automatically stops when the situation illustrated in FIG. 10 is reached. The bottom of the reversed trenches is exposed, and V-shaped grooves 26 are formed in the semiconductor areas located in between two adjacent trenches. If the wafer is effectively a (100) Si wafer, the angles α are approximately 540 in each of the V-shaped grooves 26.

It is seen that the wafer has now been thinned without requiring an etch stop layer in close proximity to the device layer 20. However, in order to achieve this result, additional conditions have to be fulfilled. The location of the bottom of the V-groove where the etch process stops depends on the depth of the trenches and on the spacing between the STI trenches, e.g., on the width of the semiconductor regions between two adjacent trenches. The latter parameter can determine whether or not the etch process reaches the frontside of the wafer before it stops automatically. Therefore, in areas of the wafer where active devices are produced on the wafer's frontside, in some embodiments, the spacing between adjacent dielectric-filled cavities (such as STI trenches) is configured so that the anisotropic etch does not reach active devices located on the wafer's frontside. In other words, the anisotropic etch in not permitted to remove semiconductor material that is contributing to the operation of active devices.

This condition has to be taken into account at the design stage, by making sure that the distance between adjacent STI trenches is not higher than a given maximum.

FIG. 10 also illustrates that a difference in the depth between two adjacent STI trenches 14 will shift the tip of the V-shaped groove 26 away from the center of the spacing between the two trenches. When the depth difference increases further, the groove is no longer a V-shaped groove, but the anisotropic etch will nevertheless stop due to its selectivity with respect to the dielectric material of the STI trenches. This is illustrated in FIG. 11. In the case shown in FIG. 11, the depth difference between a numbers of adjacent STI trenches is higher than in the embodiment shown in FIG. 10, so that the anisotropic etch stops when it reaches the material of the STI regions at locations 27. This is also an allowable example embodiment. However in most chip designs, the STI depth is targeted to be relatively uniform across a wafer, so that the case shown in FIG. 10 is more likely to occur.

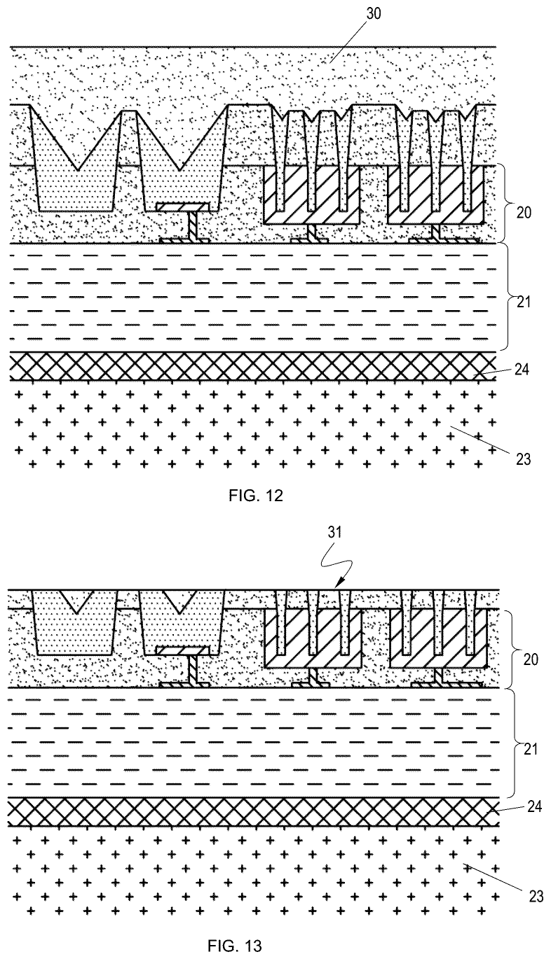

FIG. 10 will therefore be used to explain the subsequent processing steps. As shown in FIG. 12, a layer 30 of dielectric material is deposited that fills the V-grooves 26 and forms a uniform layer. In an example embodiment, the thickness of this layer is at least twice the depth of the deepest grooves (measured from the bottom of the deepest grooves). This layer 30 is then thinned, as shown in an example embodiment in FIG. 13, by grinding and/or polishing, to a level 31, wherein most of the bulk wafer material is removed. On this planarized surface 31, further processing steps may be performed, for example for producing a backside power delivery network.

As stated above, a condition that needs to be fulfilled is that the spacing between dielectric-filled cavities 14, with devices formed within the spacing on the wafer's frontside, are large enough to avoid negatively affecting the devices by the anisotropic etch process. As also indicated already, STI regions as known in chip designs can exhibit the functionality of the dielectric-filled cavities as shown in the method of the present disclosure. This does not mean however that the method is applicable to any existing chip design. In order for existing designs to be compatible with an example embodiment, some embodiments may add STI regions or adapt the spacing between existing STI regions.

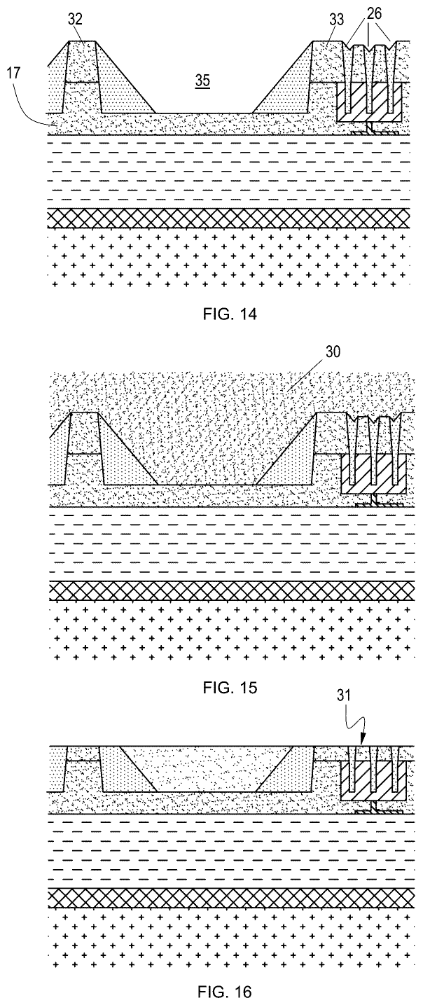

In areas of the wafer where no active devices are present, the spacing between adjacent dielectric-filled cavities can be larger, to the extent that the wafer material is removed up to the frontside of the wafer in the spacing. An example of such a spacing is shown in FIG. 14. The area between the dielectric-filled trenches 32 and 33 can, for example, be situated in a scribe line between two adjacent die areas on the wafer.

As illustrated in FIG. 14, the anisotropic etch process removes the wafer material between the trenches 32 and 33 up to the frontside of the wafer 1, creating a broad gap 35 between the trenches 32 and 33. This is not prohibited within the scope of the present disclosure, provided that the etch process stops on the PMD material 17 at the bottom of the gap 35 (selectivity of the process relative to the PMD material is shown in an example embodiment). The gap 35 is thereafter filled with the dielectric material 30 applied for filling the V-grooves 26, as shown in FIG. 15, after which the backside is planarized, as shown in FIG. 16. According to another embodiment, the anisotropic etch can be timed so that it stops before it reaches the frontside of the wafer 1 in the gap area 35.

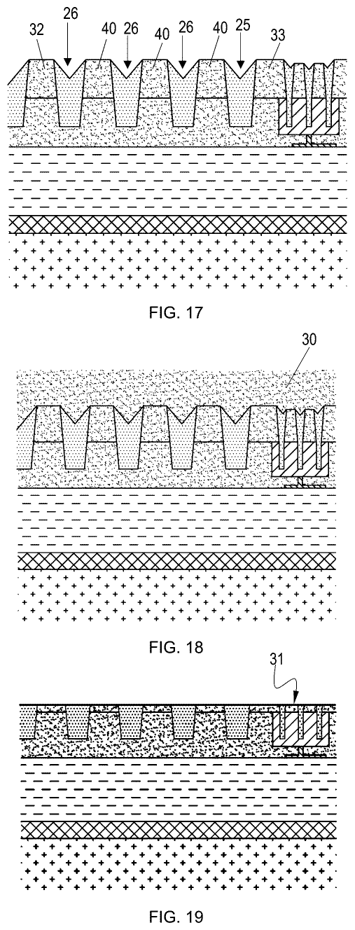

However, planarizing the large dielectric-filled gap 35 may be difficult when the surface area of this gap becomes excessively large in an example embodiment, which can lead to dishing effects. Therefore, some embodiments may deliberately provide additional dielectric-filled trenches in the areas of the wafer where no active devices are formed. This is illustrated in FIGS. 17 to 19. The spacing between the additional trenches 40 is such that also in the areas where no devices are present, the anisotropic etch stops by forming V-grooves 26 before it can reach the frontside of the wafer. This results in smaller gaps between adjacent trenches and a more planar backside after the final thinning step illustrated in FIG. 19.

While the subject matter of the present disclosure has been illustrated and described in detail in the drawings and foregoing description, such illustration and description are to be considered illustrative or exemplary and not restrictive. Other variations to the disclosed embodiments can be understood and effected by those skilled in the art in practicing the present disclosure, from a study of the drawings, the disclosure, and the appended claims. In the claims as well as in the description of this disclosure, the word “comprising” does not exclude other elements or steps, and the indefinite article “a” or “an” does not exclude a plurality. A single element may fulfill the functions of several entities or items recited in the claims. The mere fact that certain measures are recited in mutually different dependent claims does not indicate that a combination of these measures cannot be used in an example embodiment or to provide some benefit. Any reference signs in the claims should not be construed as limiting the scope.

The person skilled in the art realizes that the scope of the present disclosure is not limited to the specific embodiments described above. On the contrary, many modifications and variations are possible within the scope of, e.g., the appended claims. Variations to the disclosed embodiments can be understood and effected by the skilled person in practicing the claimed subject matter, from a study of the drawings, the disclosure, and the appended claims.

Unless specifically specified, the description of a layer being present, deposited or produced ‘on’ another layer or substrate, includes the options of: (i) the layer being present, produced or deposited directly on, i.e. in physical contact with, the other layer or substrate, and (ii) the layer being present, produced or deposited on one or a stack of intermediate layers between the layer and the other layer or substrate

While various embodiments of the present disclosure have been described above, it should be understood that they have been presented by way of example only, and not limitation. Numerous changes to the disclosed embodiments can be made in accordance with the disclosure herein without departing from the spirit or scope of the present disclosure. Thus, the breadth and scope of the present present disclosure should not be limited by any of the above described embodiments.

Although the embodiments described herein have been illustrated and described with respect to one or more implementations, equivalent alterations and modifications will occur to others skilled in the art upon the reading and understanding of this specification and the annexed drawings. In addition, while a particular feature of the present disclosure may have been disclosed with respect to only one of several implementations, such feature may be combined with one or more other features of the other implementations as may be desired for any given or particular application.

What is claimed is:

1. A method for producing a thinned semiconductor substrate, comprising:
providing a first substrate having a planar frontside and a planar backside, the first substrate comprising a crystalline semiconductor material on the planar frontside;
producing a device layer on the planar frontside of the first substrate, the device layer comprising, in a first area, a plurality of semiconductor devices;
producing, in the first area, before producing the device layer, a plurality of cavities from the planar frontside of the first substrate and into the crystalline semiconductor material of the first substrate;
at least partially filling the plurality of cavities with a dielectric material;
forming an additional dielectric layer over the plurality of semiconductor devices located in the first area;
producing an additional layer on top of the device layer, ending with a planar top surface;
bonding the first substrate to a second substrate by bonding the planar top surface to a bonding surface of the second substrate; and
subsequent to bonding the first substrate to the second substrate, thinning the first substrate from the planar backside such that a uniform layer of the crystalline semiconductor material remains above the plurality of cavities; and
subjecting the crystalline semiconductor material to an anisotropic etch process that stops at (i) a specified crystallographic plane of the crystalline semiconductor material, (ii) the dielectric material in at least one of the plurality of cavities, and (iii) the additional dielectric layer,
wherein in-plane dimensions of a plurality of regions located between the plurality of cavities and depths of the plurality of cavities are configured such that the anisotropic etch process does not reach the plurality of semiconductor devices.

2. The method of claim 1, wherein after the anisotropic etch process, the method further comprises:
depositing a further dielectric material on a thinned backside of the first substrate; and
planarizing the further dielectric material and remaining portions of the crystalline semiconductor material to a common planarized surface.

3. The method of claim 1, further comprising:
producing a second plurality of cavities in a second area of the first substrate, wherein producing the device layer does not include producing any semiconductor devices in the second area.

4. The method of claim 3, wherein a spacing between two adjacent cavities of the second plurality of cavities is configured so that the anisotropic etch process does not reach the planar frontside of the first substrate between the two adjacent cavities of the second plurality of cavities.

5. The method of claim 1, wherein the plurality of cavities in the first area define shallow trench isolation (STI) regions.

6. The method of claim 1, wherein the crystalline semiconductor material is a crystalline silicon.

7. The method of claim 6, wherein the first substrate is a silicon process wafer having the planar frontside and the planar backside oriented along the (100) crystallographic plane of the crystalline silicon.

8. The method of claim 7, wherein a plurality of scribe lines divides a plurality of die areas of the silicon process wafer.

9. The method of claim 8, wherein at least one cavity of the plurality of cavities is formed in one of the plurality of scribe lines between an adjacent pair of the plurality of die areas.

10. The method of claim 1, wherein a plurality of scribe lines divides a plurality of die areas of the first substrate, and at least one cavity of the plurality of cavities is formed in one of the plurality of scribe lines between an adjacent pair of the plurality of die areas.

11. The method of claim 1, wherein the in-plane dimensions of the plurality of regions located between the plurality of cavities and the depths of the plurality of cavities are configured such that the anisotropic etch process stops when a V-shaped groove is formed in the crystalline semiconductor material of the first substrate.

12. The method of claim 1, wherein the in-plane dimensions of the plurality of regions located between the plurality of cavities and the depths of the plurality of cavities are configured such that the anisotropic etch process stops on crystallographic planes of the crystalline semiconductor material.

13. The method of claim 1, wherein the in-plane dimensions of the plurality of regions located between the plurality of cavities and the depths of the plurality of cavities are configured such that the anisotropic etch process stops on the dielectric material in at least one of the plurality of cavities.

14. The method of claim 1, wherein the in-plane dimensions of the plurality of regions located between the plurality of cavities and the depths of the plurality of cavities are configured such that the anisotropic etch process stops on the additional dielectric layer.

15. The method of claim 2, wherein the further dielectric material is deposited after the plurality of cavities are filled at least partially with the dielectric material, to form a second layer of dielectric material.

16. The method of claim 15, wherein the further dielectric material is a pre-metal dielectric (PMD).

17. The method of claim 16, wherein the further dielectric material is at least one of SiO₂ or a low-K material.

18. The method of claim 15, wherein an interconnect via and a conductor are produced in the second layer of dielectric material.

19. The method of claim 18, wherein the interconnect via and the conductor are produced in the second layer of dielectric material by a technique comprising at least one of a single or double damascene process.

20. The method of claim 1, wherein the first substrate is bonded to the second substrate at a bonding layer comprising at least one of SiO₂, SiCN, or a hybrid bonding layer comprising the dielectric material and metal contact pads coplanar therewith.
